(19) United States
(12) Patent Application Publication
(10) Pub. No.: US 2017/0146600 A1
(43) Pub. Date: May 25, 2017

(54) Scan Logic For Circuit Designs With Latches And Flip-Flops

(71) Applicant: Microchip Technology Incorporated, Chandler, AZ (US)

(72) Inventors: Athmanathan Vaidyanathan, Gilbert, AZ (US); Eric Schroeder, Pickerington, OH (US)

(73) Assignee: Microchip Technology Incorporated, Chandler, AZ (US)

(21) Appl. No.: 15/359,692

(22) Filed: Nov. 23, 2016

Related U.S. Application Data
(60) Provisional application No. 62/259,408, filed on Nov. 24, 2015.

(51) Int. Cl. G01R 31/317; G01R 31/3177

(52) U.S. Cl. CPC G01R 31/31723; G01R 31/3177; G01R 31/31727; G01R 31/31724

(57) ABSTRACT

A system for scanning a circuit includes flip-flops and latches includes a multiplexer to couple an output of a flip-flop with an input of a latch. The multiplexer has an input receiving an input signal for the latch and another input coupled with output of the flip-flop. The system further another multiplexer to couple output of the first multiplexer with an input of another flip-flop. The system also includes scan logic for controlling multiplexers to load test data into the flip-flop and into the latch from the flip-flop. The system also includes scan logic for passing output of the flip-flop and the latch into portions of the circuit to be tested.

### RELATED PATENT APPLICATION

This application claims priority to commonly owned U.S. Provisional Patent Application No. 62/259,408; filed Nov. 24, 2015; which is hereby incorporated by reference herein for all purposes.

### TECHNICAL FIELD

The present disclosure relates to methods and systems for designing circuits with latches and/or flip-flops.

### BACKGROUND

While latches and flip-flops are similar elements, they are not identical. A latch is generally level-sensitive, whereas a flip-flop is edge-sensitive. That is, when a latch is enabled it becomes transparent, while a flip flop's output only changes on a single type of clock edge which can be either positive or negative.

### SUMMARY

In one embodiment, a method for scanning a circuit that includes flip-flops and latches includes providing a multiplexer to couple an output of a flip-flop with an input of a latch. The multiplexer has an input receiving an input signal for the latch and another input coupled with output of the flip-flop. The method further includes providing another multiplexer to couple output of the first multiplexer with an input of another flip-flop. The method also includes controlling multiplexers to load test data into the flip-flop and into the latch from the flip-flop. The method also includes passing output of the flip-flop and the latch into portions of the circuit to be tested.

In another embodiment, a system for scanning a circuit that includes flip-flops and latches includes a multiplexer to couple an output of a flip-flop with an input of a latch. The multiplexer has an input receiving an input signal for the latch and another input coupled with output of the flip-flop. The system further another multiplexer to couple output of the first multiplexer with an input of another flip-flop. The system also includes scan logic for controlling multiplexers to load test data into the flip-flop and into the latch from the flip-flop. The system also includes scan logic for passing output of the flip-flop and the latch into portions of the circuit to be tested.

### BRIEF DESCRIPTION OF THE DRAWINGS

FIG. 1 is an illustration of an example system for scanning a circuit, according to embodiments of the present disclosure;

FIG. 2 illustrates an example of parts of a circuit that may be tested, according to embodiments of the present disclosure.

FIG. 3 illustrates an example of other parts of a circuit that may be tested, according to embodiments of the present disclosure

FIG. 4 illustrates an example of further parts of a circuit that may be tested, according to embodiments of the present disclosure

FIG. 5 illustrates an example of still further parts of a circuit that may be tested, according to embodiments of the present disclosure.

FIG. 6 illustrates an example of parts of a circuit including flops, latches, and other circuitry that may be tested, according to embodiments of the present disclosure;

FIGS. 7A, 7B, and 7C illustrate an example timing diagram for testing a circuit, in accordance with embodiments of the present disclosure; and

FIG. 8 illustrates an example method for testing a circuit, according to embodiments of the present disclosure.

### DETAILED DESCRIPTION

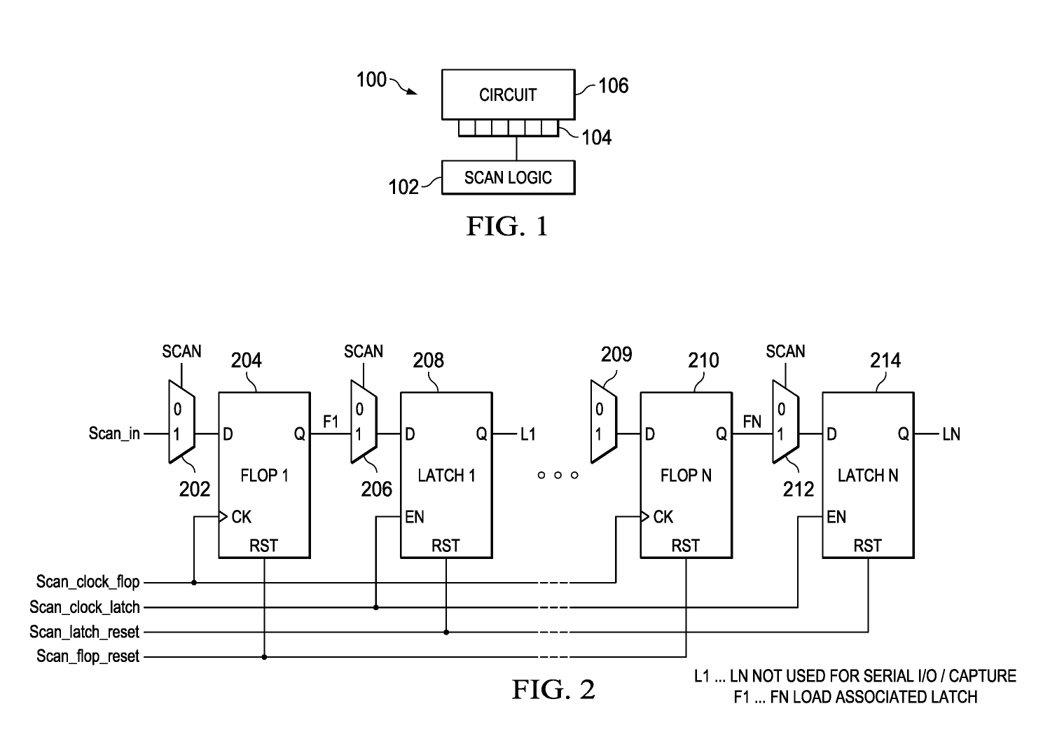

FIG. 1 is an illustration of an example system 100 for scanning a circuit. The circuit may include latches and flip-flops. The latches and flip-flops may be used to pass information into and out of the circuit, wherein the information is to be used in testing the circuit. System 100 may include any suitable number and kind of components. For example, system 100 may include scan logic 102. Scan logic 102 may specify a series of inputs that are to be applied through circuit interfaces 104 to the circuit 106 under test. Scan logic 102 may be implemented by, for example, analog circuitry, digital circuitry, instructions for execution by a processor, or any other suitable mechanism. Circuit interfaces 104 may include, for example, test harnesses, leads, interconnects, or other suitable mechanisms to connect to pins of circuit 106 under test. Circuit 106 may include circuitry that is included within or on, for example, a die, chip, package, substrate, or any other suitable mechanism for hosting circuit 106.

In one embodiment, circuit 106 may include latches and flops (flip-flops). The latches and flops may be connected in series to form any suitable circuit construct, such as a shift register, microprocessor, execution, unit, etc. Moreover, the latches and flops may interface other portions of circuit 106 that are to be tested. Each such latch or flop may be implemented in any suitable manner. In another embodiment, a previous version of circuit 106 that had the same functional output as circuit 106 was modified to replace one or more flops with one or more latches. However, as discussed below, even if the functionality of a flop or a latch might be performed conversely by the other of a flop or a latch, testing a design with a flop and a latch require different considerations.

Performance of scanning or testing of circuit 106 may include applying, through circuit interfaces 104, specified inputs into portions of circuit 106 and evaluating outputs received through circuit 106 resulting from such inputs and the operation of circuit 106. The inputs may be specified by scan logic 102. The results of scanning or testing may be stored in a computer-readable medium for later evaluation by a suitable entity, or evaluated by scan logic 102. Comparison of the results against expected results may provide insight whether circuit 106 includes any defects. The inputs to be applied to circuit 106 and the expected results from circuit 106 may depend upon a particular model or makeup of circuit 106. Accordingly, an appropriate set of test vectors may be applied for a given instance of circuit 106.

In one embodiment, testing and scanning an instance of circuit 106 that includes a latch may be more difficult than an instance of circuit 106 that includes only flops. This may occur because when a latch remains open during an “enabled” period of its operation, data feedthrough will not be made to multiple latches. One work-around to this problem is to keep the latches transparent, wherein the gate for the latch is kept at a logic one, or constantly activated. However, using this approach, which might be used for a design with relatively few latches, may cause significantly poor coverage in design for most applications. For example, an 8-bit microcontroller may have a large number of latches. Not latches in such a device will be actually tested during the scanning. Furthermore, if phased clocks are used for shifting in data to the latches, then based on number of phases, multiple latches may get loaded with the same data. For example, a number of latches with the same data may be equivalent to a number of phases of the clock. This may cause difficulty in controlling the test vectors. Also, use of phased clocks during capture of output data may cause successive captures of different phases to change according to a previous capture, making debugging difficult. In one embodiment, system 100 may solve one or more of these problems with reduced area on die and time overhead while achieving testability approaching that of a circuit with all flops.

In one embodiment, system 100 may be used to test designs of circuit 106 that include relative equivalent amounts of flops and latches, wherein the total combination of flops and latches are approximately fifty percent of each of flops and latches. For example, various instances of circuit 106 may include 48% or 45% flops, as compared to 52% or 55% latches. In a further embodiment, a design of circuit 106 may be modified to convert excess latches (or flops) to flops (or latches) to achieve an equal number of latches and flops. Design of circuit 106 may take into account size of latches and flops. For example, latches may be smaller on a surface die than flops. Thus, latches may be preferable to flops. However, testing of a circuit that is entirely made up of flops may be easier than testing of latches, as described above. In another embodiment, system 100 may be configured to test a design of circuit 106 that includes an equal number or roughly equal number of flops and latches as efficiently or nearly as efficiently as a circuit that is made up of all flops (as opposed to any latches).

In one embodiment, system 100 may perform scanning on flops or latches by using a shift-in-vector for sequential elements (flops or latches), wherein data is populated to a tested entity. In another embodiment, system 100 may perform scanning on flops or latches by fanning out the shifted-in-vector to other elements. In yet another embodiment, system 100 may perform scanning on flops or latches by capturing a snapshot of data, or a mission mode. In another embodiment, system 100 may perform scanning on flops or latches by shifting out the captured data. Circuit 106 may be designed to be tested so that element layouts avoid using latches for any of these steps except fanning out values. According to various embodiments, it is proposed to make use of available flops to act as lock up latches for the latches. According to various embodiments, real life practical designs can be achieved with half the number of flops to help solve various problems of using latches.

Latches might not efficiently shift in data, capture or shift out data. Latches are able to fan out the vector to the whole circuit as long as the latch somehow receives the vector. Flops and latches may be arranged in circuit 106 so that flops in the design may assist the latches in the remaining 3 functions (shift in/shift out and capture) with minimum time and area overhead and minimum loss of coverage.

FIG. 2 illustrates an example embodiment of part of a circuit that may be tested by system 100, according to embodiments of the present disclosure. FIG. 2 may illustrate wiring for test and scanning, and may reflect some modifications of a previous instance of circuit 106. For example, for a given series of elements that can be implemented by flops or latches in circuit 106, flops and latches may be interleaved on a 1:1 basis as shown in FIG. 2. Flops 204, 210 may be staged in advance of respective ones of latches 208, 214. Flops 204, 210 and latches 208, 214 may be controlled through an overall scan signal, a scan clock for flops, a scan clock for latches, a reset signal for latches, and a reset signal for flops. The overall scan signal may be applied to respect multiplexers 202, 206, 209, 212 for each element. The scan signal may enable, through respective multiplexers, the transfer of data between elements.

In one embodiment, flops 204, 210 may receive their scan data from a scan_in signal. However, latches 208, 214 may receive their scan_in information as processed from respective flops 204, 210. Latches might only receive their scan_in information from flops. Latches may be unable to capture, and so their output might not be used in scan connections. Flops 204, 210 might now act as a lockup latch to respective latches 208, 214, thereby stopping a feedthrough and without the need for adding extra lock up latches. Latches 208, 214 might now operate on a single phase clock with no skew balancing required between latch clocks.

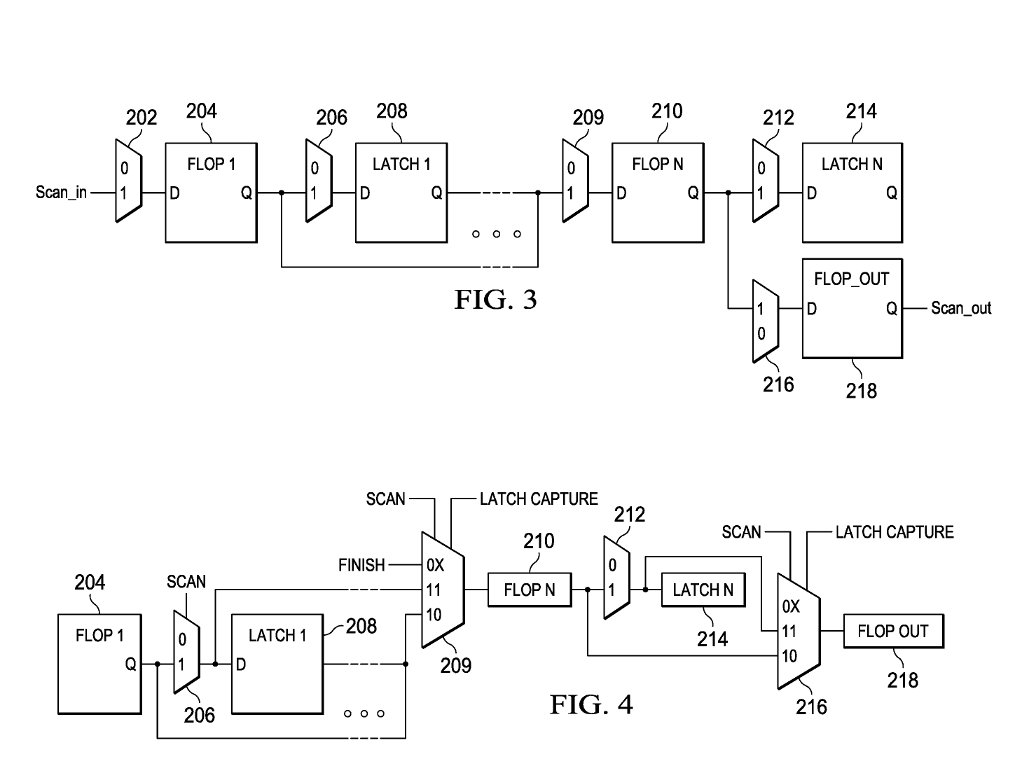

FIG. 3 illustrates an example embodiment of other parts of a circuit that may be tested by system 100, according to embodiments of the present disclosure. FIG. 3 may illustrate wiring for test and scanning, and may reflect some modifications of a previous instance of circuit 106. FIG. 3 may illustrate changes made to the circuit of FIG. 2.

In FIG. 3, flops 204, 210 may be stitched together, along with another, similarly configured output flop 218. Flops 204, 210, 218 may be stitched together in a straight chain by routing the output of a given flop to the next flop (in addition to the corresponding latch). Shifting scan or test bits is performed only by flops, so the chain connection is made between the flops. The output of a given flop may be routed to the next flop through that next flop's multiplexer, such as multiplexer 209, 216.

FIG. 4 illustrates an example embodiment of further parts of a circuit that may be tested by system 100, according to embodiments of the present disclosure. FIG. 3 may illustrate wiring for test and scanning, and may reflect some modifications of a previous instance of circuit 106. FIG. 4 may illustrate changes made to the circuit of FIG. 3.

While latches cannot be used for capturing data in the same manner as a flop, the output of such latches should be evaluated with respect to the scan or test bits that are passed into the latches and the expected output. Accordingly, instead of 2:1 multiplexers for each flop, a 3:1 multiplexer may be used. The third input of the multiplexer for the flop may be used to capture the latch input data that the latches cannot otherwise capture. This may be accomplished by routing the output of a latch multiplexer 206, 212 to one of the inputs of the next flop multiplexer 209, 216. The same vectors might be loaded again and the latch data captured in the second iteration. Accordingly, the flops may be enabled to perform shifting in data, capturing data, and shifting out data.

The 3:1 multiplexer may include an input for function_in (input from other portions of circuit 106, not shown), holding the value when applied to the flop and dependent upon the scan control signal, as also performed in the 2:1 multiplexers. The 3:1 multiplexer may include an additional mux control input for capturing latch data. The 3:1 multiplexer may include two inputs to be controlled by the latch capture signal when the scan signal is also enabled. When latch capture is not enabled and the scan capture is enabled, the multiplexer will route the previous flop data to the flop. When latch capture is enabled and the scan capture is enabled, the multiplexer will route the previous latch multiplexer output to the flop.

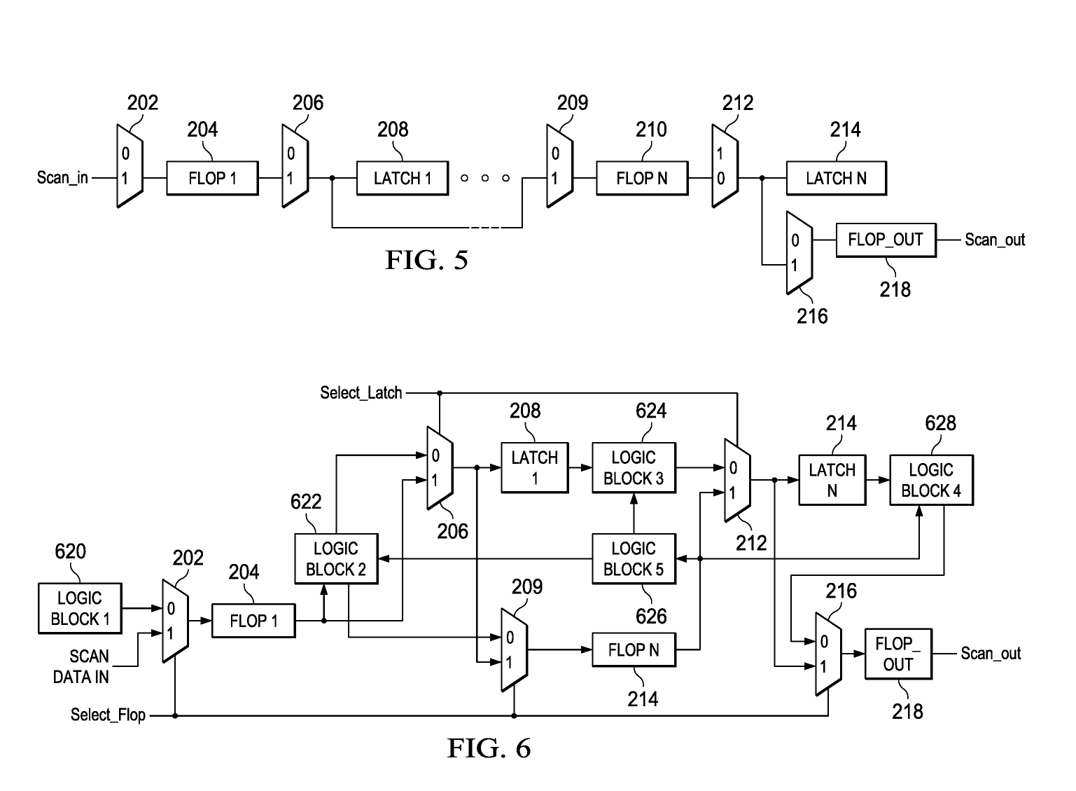

FIG. 5 illustrates an example embodiment of still further parts of a circuit that may be tested by system 100, according to embodiments of the present disclosure. FIG. 5 may illustrate wiring for test and scanning, and may reflect some modifications of a previous instance of circuit 106. FIG. 5 may illustrate changes made to the circuit as presented in previous figures.

In FIG. 5, the two inputs on a given latch multiplexer also are the two inputs to the next flop multiplexer. This may be optimized by using the output of the latch multiplexer and reducing the flop multiplexer back to a 2:1 multiplexer. The multiplexer select signals and scan clocks are coordinated to control the data flow as desired.

FIG. 6 illustrates an example embodiment of parts of a circuit including flops, latches, and other circuitry that may be tested by system 100, according to embodiments of the present disclosure.

In particular, FIG. 6 illustrates how latches and flops may be tested while such latches and flops are integrated into other portions of circuit 106. For example, flops 204, 214 and latches 208, 214 may be interconnected with various other digital or analog circuitry of circuit 106. Flops 204, 214 and latches 208, 214 may consume or produce values that are imported from or exported to such circuitry. Such circuitry may be represented in FIG. 6 by logic blocks 620, 622, 624, 626, 628. Although a particular arrangement of logic blocks 620, 622, 624, 626, 628 is shown with respect to flops 204, 214 and latches 208, 214, the illustration of FIG. 6 is presented as but one example and should not be considered limiting. Any suitable number or kind of logic blocks interfacing with flops 204, 214 and latches 208, 214 may be used, just as any suitable number of flops and latches may be used. Moreover, any suitable arrangement of logic blocks, flops, and latches may be used. The particular logic blocks 620, 622, 624, 626, 628 represent the functionality that circuit 106 is to perform. System 100 may test flops 204, 214 and latches 208, 214 with respect to their interaction with such logic blocks. For example, logic block 620 may provide a data bit to flop 204. Such a data bit may be multiplexed with respect to scan data in. In another example, flop 214 may export a data bit to logic block 626, which may in turn export a data bit to latch 214.

Each multiplexer 202, 209, 216 associated with flops may have a specified trigger signal, scan_flop. Likewise, each multiplexer 206, 212 associated with latches may have a specified trigger signal, scan_latch.

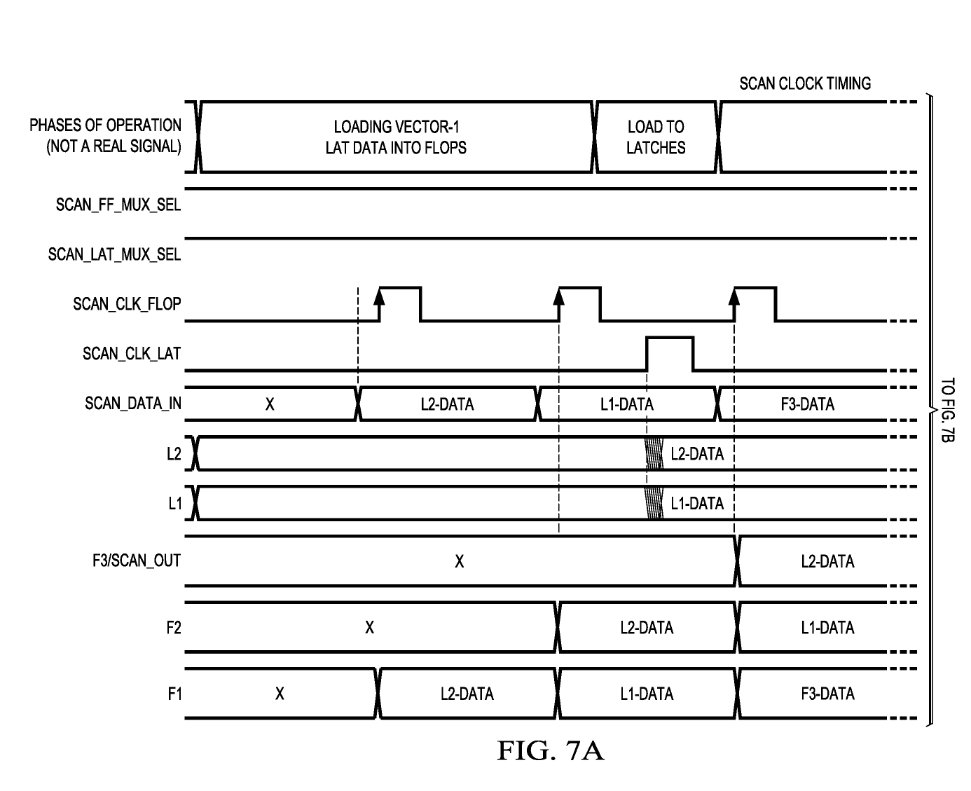

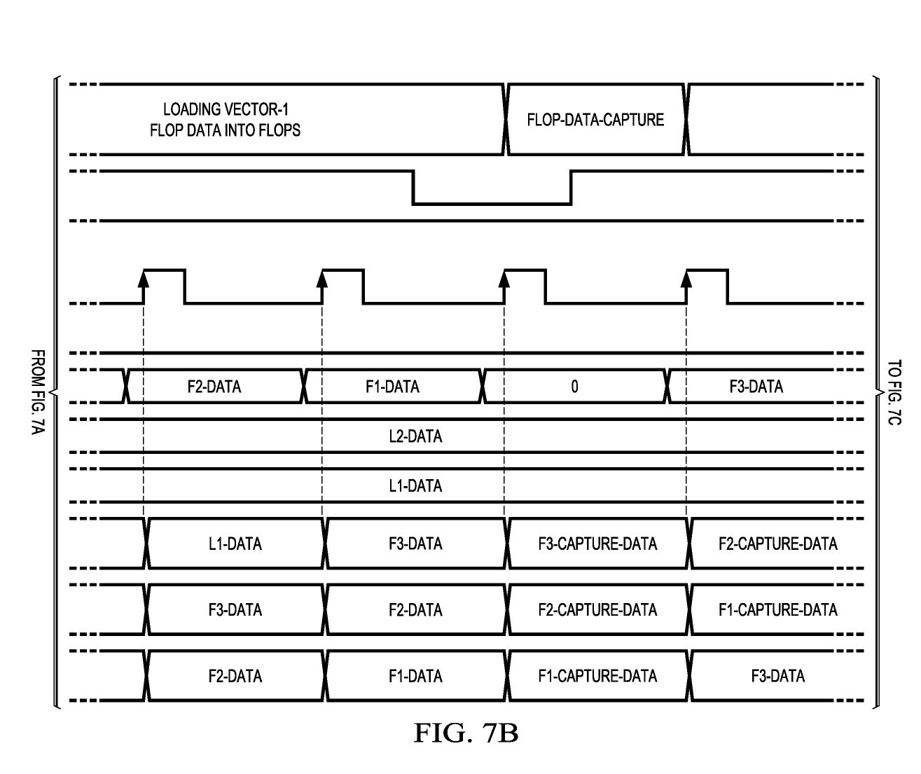

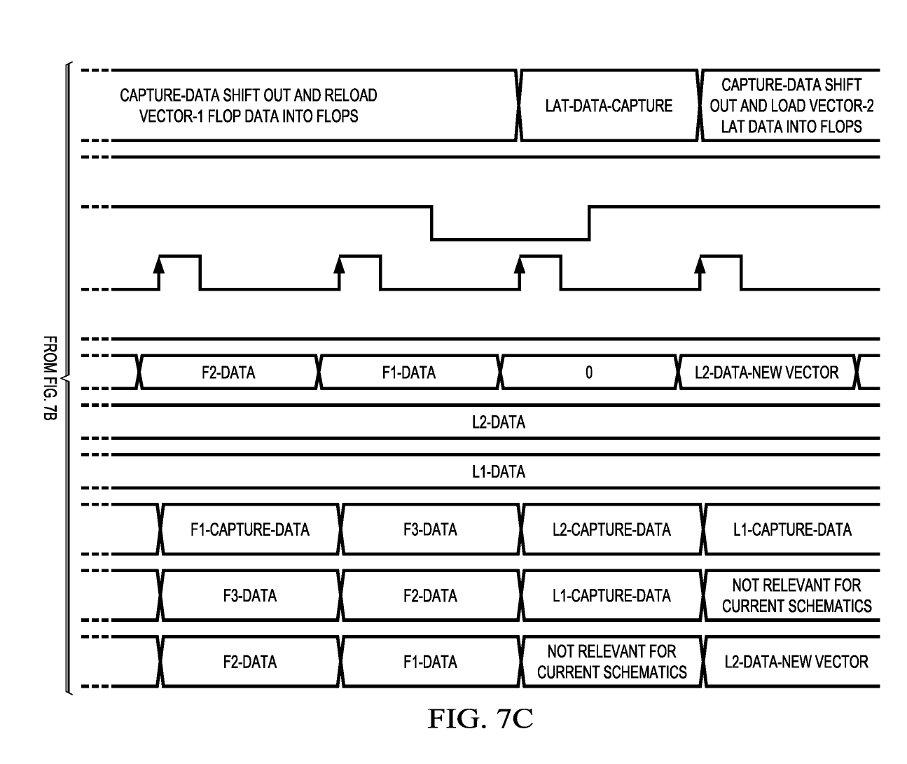

FIGS. 7A, 7B, and 7C illustrate an example timing diagram, in accordance with embodiments of the present disclosure. The timing diagram of these figures may illustrate operation of testing of circuit 106 as shown in FIG. 6 as performed by system 100.

A scan_ff_mux_sel signal is shown, which may illustrate operation of select_flop from FIG. 6.

A scan_lat_mux_sel signal is shown, which may illustrate operation of select_latch from FIG. 6.

A scan_clk_flop signal is shown, which may illustrate operation of scan_clok_flop routed into each of the flops. The connection of this signal was shown in FIG. 2.

A scan_clk_lat signal is shown, which may illustrate operation of scan_clok_latch routed into each of the flops. The connection of this signal was shown in FIG. 2.

A scan_data_in signal is shown, which may illustrate operation of scan_data_in to populate flops with test or scan bits.

L1 and L2 signals are shown, which may illustrate the output of latches 208, 214. An F3/scan_out signal is shown, which may illustrate the output of flop 218. F1 and F2 signals are shown, which may illustrate the output of flops 204, 214.

In operation, during a first phase of testing circuit 106, data is loaded into the flops. Flops can shift in and shift out data serially. In the first phase, the flops take in test data. The flops are first loaded with vector data intended for the latches. Flops 204, 214 take in data to be used by latches 208, 214, respectively. SCAN_FF_MUX_SEL is set to a logical one signal, such that the multiplexer selects the scan_data_in pin. The lops are all serially connected like a serial shift register. SCAN_CLK_FLOP may clock the flops to load the vector data (meant for latches) into the flops serially. SCAN_CLK_LAT might inactive, unused, or irrelevant during this phase. SCAN_DATA_IN is an input pin that is supplied with the vector data from outside circuit 106 from scan logic 102.

During a second phase of testing circuit 106, data in flops 204, 214 are loaded into latches 208, 214, respectively, in parallel. This may occur in a single clock cycle. The value of SCAN_DATA_IN, SCAN_FF_MUX_SEL and SCAN_CLK_FLOP may be irrelevant, as flops might be unclocked during this phase. The value of SCAN_LAT_MUX_SEL may be set to a logical one, wherein latch multiplexers 206, 212 may select the select_in pin, allowing data in the flops to be the data input to the latches, thus loading the data from flops to the latches. SCAN_CLK_LAT may be clocked once to load all the latches simultaneously.

During a third phase of testing circuit 106, the flops may be loaded with their own information. This may occur after the flops have been used to populate data to the latches. The control signals are similar to the first phase but the SCAN_DATA_IN input pins shift in a new set of vector data intended to be loaded in flops 204, 214.

SCAN_FF_MUX_SEL may be set to a logical high value. Accordingly, flop multiplexers may select the scan_in pins. SCAN_LAT_MUX_SEL may be set to a logical high value, wherein latch multiplexers may select the scan_in pin. These two signals may insure that all the flops are serially connected like a serial shift register. SCAN_CLK_FLOP may clock the flops to load the vector data (meant for flops) into the flops serially. SCAN_CLK_LAT might be inactive. SCAN_DATA_IN may include vector data to be used in testing.

During a fourth phase of testing circuit 106, resulting data may be captured from the flops. The result may be loaded into the flops. The flops may be loaded with the captured at the rising edge of the clock diagram.

SCAN_FF_MUX_SEL may be held to a logical zero, so that the flop multiplexers select functional data for routing. The value of SCAN_LAT_MUX_SEL, SCAN_CLK_LAT, and SCAN_DATA_IN may be irrelevant, as latches are not clocked in the phase, the flop multiplexers are selecting functional data, and the flops are not inputting data from SCAN_DATA_IN. SCAN_CLK_FLOP may clock the flops once to capture the functional data in into the flops.

During a fifth phase of testing circuit 106, data captured by the flops may be serially shifted out while original flop vector data is shifted in again. Thus, the capture data to be evaluated may be output and the flop data reloaded. At the conclusion of the fifth phase, all flops and latches may be returned to a state akin to the third phase, before the flop data is captured. The captured data appears at the output of output flop 218, while flops 204, 214 are loaded with the vector again. The vector is loaded again in order to complete a capture for latch data. The latches were not clocked since the first load, so they do not require loading again.

SCAN_FF_MUX_SEL may be set to a logical one value, such that the flop multiplexers select the scan_in pin. SCAN_LAT_MUX_SEL may be set to a logical one value, such that latch multiplexers select the scan_in pin. These two signals make all flops connected in a manner like a serial shift register. SCAN_CLK_FLOP may clock the flops to load the vector data into the flops serially again while shifting out the captured data from the other end of the chain. SCAN_CLK_LAT might be inactive during this phase.

During a sixth phase of testing circuit 106, functional data at the input of the latches may be captured into the flops. The flops may be loaded with captured data at the rising edge of the clock timing diagram. The functional data at the input of the latches may be later output and compared against expected values.

SCAN_FF_MUX_SEL may be set to a logical one value, such that the flop multiplexers select the scan_in pin. SCAN_LAT_MUX_SEL may be set to logical zero, so that the combination of multiplexers selects functional data into the input of flop. SCAN_CLK_FLOP may clock the flops once to capture the latches' functional data in into the flops. SCAN_CLK_LAT might be inactive during this phase.

In a seventh phase of testing circuit 106, data captured by the flops (from the latches) may be serially shifted out while the next vector of test data is loaded. The captured data is output from output flop 218 while flops 204, 214 are loaded with the next vector of data.

SCAN_FF_MUX_SEL may be set to a logical one, such that flop multiplexers select the scan_in pin. SCAN_LAT_MUX_SEL may be set to a logical one, such that latch multiplexers select the scan_in pin. SCAN_CLK_FLOP clocks the flops to load the new vector data into the flops serially again while shifting out the captured data from the other end of the chain. SCAN_CLK_LAT is inactive during this phase.

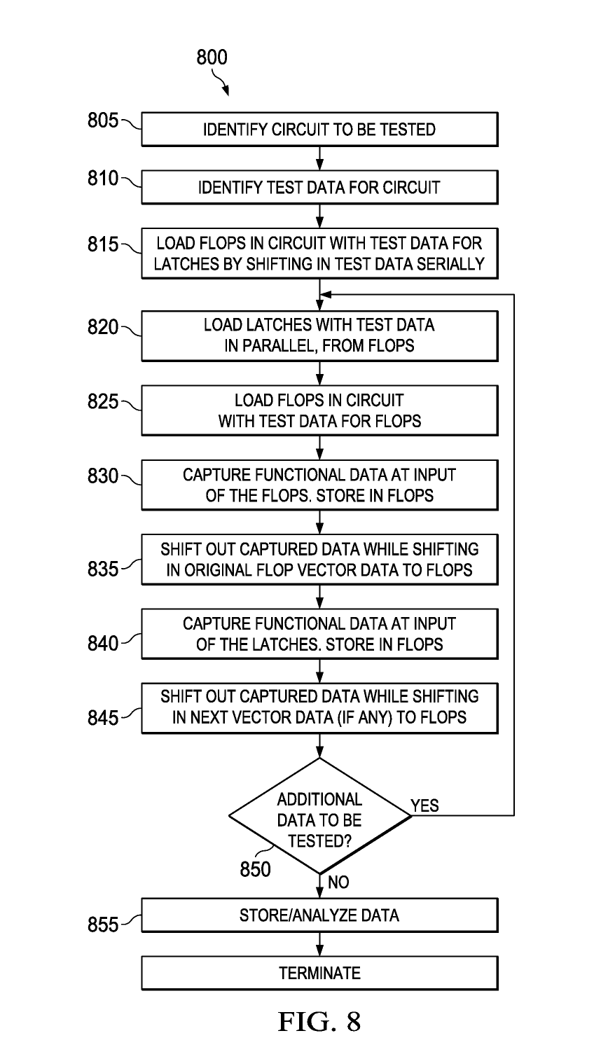

FIG. 8 illustrates an example method 800 for testing a circuit, according to embodiments of the present disclosure.

At 805, a circuit to be tested may be identified. The circuit may require a particular set of test data to be executed across various logic blocks or portions of circuitry therein. At 810, appropriate test data and control signals to test the circuit may be retrieved or identified based upon the type of circuit.

At 815, flops in the circuit may be loaded with test vector data. The test vector data may correspond to latches that are to be tested. The test data may be loaded in the test vectors by shifting in the data serially.

At 820, latches may be loaded with test data. The test data may be transferred from the flops. The test data may be issued in parallel.

At 825, flops in the circuit may be loaded with their own test data.

After test bits have travelled from the flops and latches to various portions of the circuit under test, at 830, the resulting data may be harvested for comparison against expected values. The functional data generated may be captured at the flops. The result might itself be stored in the flops. At 835, the results may be shifted out while the original flop vector data may be shifted in to the flops. At 840, functional data may be captured at the latches and stored into the flops. At 845, such captured data may be shifted out from the flops. If additional test data is to be processed, the test data may be loaded into the flops.

At 850, if there is additional data that is to be tested, method 800 may proceed to 820. Otherwise, at 855, data retrieved during the scanning and testing process may be stored, written, or analyzed as necessary. Method 800 may terminate.

Method 800 may be implemented by any suitable mechanism, such as by system 100 and the elements of one or more of FIGS. 1-7. Method 800 may optionally repeat or terminate at any suitable point. Moreover, although a certain number of steps are illustrated to implement method 800, the steps of method 800 may be optionally repeated, performed in parallel or recursively with one another, omitted, or otherwise modified as needed. Method 800 may initiate at any suitable point, such as at 805.

Although example embodiments have been described above, other variations and embodiments may be made from this disclosure without departing from the spirit and scope of these embodiments.

1. A method for scanning a circuit comprising a plurality of flip-flops and latches, the method comprising:
providing a first multiplexer to couple an output of a first flip-flop with an input of a first latch, wherein the first multiplexer has a first input receiving an input signal for the first latch and a second input coupled with output of the first flip-flop;
providing a second multiplexer to couple output of the first multiplexer with an input of a second flip-flop;
controlling the first and second multiplexers to load test data into the first flip-flop and into the first latch from the first flip-flop; and
passing output of the first flip-flop and the first latch into portions of the circuit to be tested.

2. The method according to claim 1, wherein the first flip-flop acts as a lock-up latch for the first latch.

3. The method according to claim 1, wherein the first flip-flop and the first latch receive separate scan clock signals.

4. The method according to claim 1, wherein the first multiplexer and the second multiplexer receive separate enable signals.

5. The method according to claim 1, further comprising routing a first circuit logic to an input of the first multiplexer, wherein the first circuit logic is configured to provide a signal to the latch during non-scanning operation.

6. The method according to claim 5, further comprising loading result data from the first flip-flop and the first latch, the result data to indicate processing of test data by the first circuit logic.

7. The method according to claim 1, further comprising capturing first result data from the first flip-flop reflecting performance of the circuit to be tested.

8. The method according to claim 7, further comprising, after capturing the first result data from the first flip-flop, loading the same test data back into the first flip-flop.

9. The method according to claim 8, further comprising, after loading the same test data back into the first flip-flop, capturing second result data from the first latch reflecting performance of the circuit to be tested and storing the second result data into the first flip-flop.

10. The method according to claim 9, further comprising, after storing the second result data into the first flip-flop, simultaneously shifting out the second result data and shifting in new test data to the first flip-flop.

11. A system for scanning a circuit comprising a plurality of flip-flops and latches, the system comprising:
a first multiplexer configured to couple an output of a first flip-flop with an input of a first latch, wherein the first multiplexer has a first input for receiving an input signal for the first latch and a second input coupled with output of the first flip-flop;
a second multiplexer configured to couple output of the first multiplexer with an input of a second flip-flop; and
scan logic configured to:
control the first and second multiplexers to load test data into the first flip-flop and into the first latch from the first flip-flop; and
pass output of the first flip-flop and the first latch into portions of the circuit to be tested.

12. The system according to claim 11, wherein the first flip-flop is configured to perform as a lock-up latch for the first latch.

13. The system according to claim 11, wherein the first flip-flop and the first latch are configured to receive separate scan clock signals.

14. The system according to claim 11, wherein the first multiplexer and the second multiplexer are configured to receive separate enable signals.

15. The system according to claim 11, wherein the scan logic is further configured to route a first circuit logic coupled to an input of the first multiplexer, wherein the first circuit logic is configured to provide a signal to the latch during non-scanning operation.

16. The system according to claim 15, wherein the scan logic is further configured to cause loading of result data from the first flip-flop and the first latch, the result data to indicate processing of test data by the first circuit logic.

17. The system according to claim 11, wherein the scan logic is further configured to route capturing first result data from the first flip-flop reflecting performance of the circuit to be tested.

18. The system according to claim 17, wherein the scan logic is further configured to cause, after capturing the first result data from the first flip-flop, loading the same test data back into the first flip-flop.

19. The system according to claim 18, wherein the scan logic is further configured to cause, after loading the same test data back into the first flip-flop, capturing second result data from the first latch reflecting performance of the circuit to be tested and storing the second result data into the first flip-flop.

20. The system according to claim 19, wherein the scan logic is further configured to cause, after storing the second result data into the first flip-flop, simultaneously shifting out the second result data and shifting in new test data to the first flip-flop.
